(19) United States
(12) Patent Application Publication
(10) Pub. No.: US 2025/0294886 A1
(43) Pub. Date: Sep. 18, 2025

(54) METHODS FOR SINGULATING SEMICONDUCTOR DIE FROM SILICON CARBIDE SUBSTRATES

(71) Applicant: SEMICONDUCTOR COMPONENTS INDUSTRIES, LLC, Scottsdale, AZ (US)

(72) Inventors: Ian Ceazar Bucayon BARIAS, Butuan City (PH); ZhenLiang LU, Suzhou (CN); Shuai WANG, SuZhou (CN)

(73) Assignee: SEMICONDUCTOR COMPONENTS INDUSTRIES, LLC, Scottsdale, AZ (US)

(21) Appl. No.: 18/606,952

(22) Filed: Mar. 15, 2024

(51) Int. Cl. H01L 21/784; B23K 26/53

(52) U.S. Cl. CPC H10D 89/013; B23K 26/53

(57) ABSTRACT

Implementations of a method of singulating silicon carbide may include in a plurality of X-direction die streets, irradiating with a laser beam focused at a focal point a first depth into the thickness in a predetermined number of X-passes to form a first modified region and a second modified region. The method may also in include irradiating in a Y-direction with the laser beam focused a focal point a second depth into the thickness in a predetermined number of Y-passes to form a first modified region and a second modified region. The method may include breaking first in the Y-direction and then in the X-direction along the plurality of X-direction die streets and the plurality of Y-direction die streets, respectively, using an anvil. The method also may include expanding a tape to separate a plurality of die from the silicon carbide substrate.

### BACKGROUND

### 1. Technical Field

Aspects of this document relate generally to systems and systems for singulating semiconductor die from semiconductor substrates. More specific implementations involve singulating semiconductor die from silicon carbide substrates.

### 2. Background

Semiconductor substrates are utilized for the purpose of creating various semiconductor devices thereon. Many different types of semiconductor devices have been devised, including transistors, diodes, rectifiers, and the like.

### SUMMARY

Implementations of a method of singulating silicon carbide may include providing a silicon carbide substrate including a thickness. The method may include in a plurality of X-direction die streets: irradiating the silicon carbide substrate in an X-direction with a laser beam focused at a first focal point a first distance into the thickness in a first X-pass; irradiating the silicon carbide substrate in the X-direction with the laser beam focused at a second focal point a second distance into the thickness in a second X-pass; and irradiating the silicon carbide substrate in the X-direction with the laser beam focused at a third focal point a third distance into the thickness in a third X-pass. The method may also include in a plurality of Y-direction die streets: irradiating the silicon carbide substrate in a Y-direction with the laser beam focused a first focal point a first distance into the thickness in a first Y-pass; irradiating the silicon carbide substrate in a Y-direction with the laser beam focused a second focal point a second distance into the thickness in a second Y-pass; irradiating the silicon carbide substrate in a Y-direction with the laser beam focused a third focal point a third distance into the thickness in a third Y-pass; irradiating the silicon carbide substrate in a Y-direction with the laser beam focused a fourth focal point a fourth distance into the thickness in a fourth Y-pass; and irradiating the silicon carbide substrate in a Y-direction with the laser beam focused a fifth focal point a fifth distance into the thickness in a fifth Y-pass. The method may include breaking the silicon carbide substrate in the X-direction and in the Y-direction along the plurality of X-direction die streets and the plurality of Y-direction die streets, respectively, using an anvil; and expanding a tape coupled to the silicon carbide substrate to separate a plurality of die from the silicon carbide substrate.

Implementations of method of singulating silicon carbide may include one, all, or any of the following:

The first distance in the first X-pass may be further into the thickness than the second distance in the second X-pass and the second distance in the second X-pass may be further into the thickness than the third distance in the third X-pass.

The first distance in the first X-pass may be −26 microns, the second distance in the second X-pass may be −19 microns, and the third distance in the third X-pass may be −13 microns.

The first distance in the first Y-pass may be further into the thickness than the second distance in the second Y-pass; the second distance in the second Y-pass may be further into the thickness than the third distance in the third Y-pass; the fourth distance in the fourth Y-pass may be further into the thickness than the third distance in the third Y-pass; and the fourth distance in the fourth-Y-pass may be further into the thickness than the fifth distance in the fifth Y-pass.

The first distance in the first Y-pass may be −26 microns, the second distance in the second Y-pass may be −21 microns, the third distance in the third Y-pass may be −13 microns, the fourth distance in the fourth Y-pass may be −17 microns, and the fifth distance in the fifth Y-pass may be −14 microns.

The scan speed used in the first Y-pass, the second Y-pass, the fourth Y-pass, and the fifth Y-pass may be 510 mm/second and a scan speed used in the third Y-pass may be 150 mm/second.

The scan speed used in the first X-pass, the second X-pass, and the third X-pass may be 525 mm/second.

A laser power used in the first X-pass, the second X-pass, and the third X-pass may be 0.18 W; a laser power used in the first Y-pass, the second Y-pass, the fourth Y-pass, and the fifth Y-pass may be 0.23 W; and a laser power used in the third Y-pass may be 0.04 W.

Implementations of a method of singulating silicon carbide may include providing a silicon carbide substrate including a thickness; and in a plurality of X-direction die streets, irradiating the silicon carbide substrate in an X-direction with a laser beam focused at a focal point a distance into the thickness in a predetermined number of X-passes; and in a plurality of Y-direction die streets, irradiating the silicon carbide substrate in a Y-direction with the laser beam focused a focal point a distance into the thickness in a predetermined number of Y-passes. The method may include breaking the silicon carbide substrate first in the Y-direction and then in the X-direction an along the plurality of X-direction die streets and the plurality of Y-direction die streets, respectively, using an anvil at a predetermined over travel height, an anvil distance of 0.39 mm, and a chopper drop speed of 20 mm/second. The method may include expanding a tape coupled to the silicon carbide substrate to separate a plurality of die from the silicon carbide substrate at a temperature of 60 C.

Implementations of a method of singulating silicon carbide may include one, all, or any of the following:

The thickness of the silicon carbide substrate may be 100 microns and the predetermined over travel height may be 1.2 mm.

The thickness of the silicon carbide substrate may be 200 microns and the predetermined over travel height may be 1.12 mm.

Expanding the tape further may include expanding at an expansion height of 8 mm, an expansion speed of 10 mm/second, and a hold time of 30 seconds.

Implementations of a method of singulating silicon carbide may include providing a silicon carbide substrate including a thickness; and in a plurality of X-direction die streets, irradiating the silicon carbide substrate in an X-direction with a laser beam focused at a focal point a first depth into the thickness in a predetermined number of X-passes to form a first modified region beginning a first distance into the thickness and a second modified region a second distance into the thickness. The method may also in include in a plurality of Y-direction die streets, irradiating the silicon carbide substrate in a Y-direction with the laser beam focused a focal point a second depth into the thickness in a predetermined number of Y-passes to form a first modified region a first distance into the thickness and a second modified region a second distance into the thickness. The method may include breaking the silicon carbide substrate first in the Y-direction and then in the X-direction an along the plurality of X-direction die streets and the plurality of Y-direction die streets, respectively, using an anvil. The method also may include expanding a tape coupled to the silicon carbide substrate to separate a plurality of die from the silicon carbide substrate.

Implementations of a method of singulating silicon carbide may include one, all, or any of the following:

In the X-direction, the first distance may be between 20 microns to 32 microns and the second distance may be between 39 microns and 56 microns when the thickness of the silicon carbide substrate is 100 microns.

In the Y-direction, the first distance may be between 21 microns to 33 microns and the second distance may be between 38 microns and 58 microns when the thickness of the silicon carbide substrate is 100 microns.

In the X-direction, the first distance may be between 22 microns to 35 microns and the second distance may be between 43 microns and 62 microns when the thickness of the silicon carbide substrate is 200 microns.

In the Y-direction, the first distance may be between 43 microns to 62 microns and the second distance may be between 44 microns and 63 microns when the thickness of the silicon carbide substrate is 200 microns.

Consistent breaking of the silicon carbide substrate may occur when the first modified region and the second modified region in the X-direction meet and when the first modified region and the second modified region in the Y-direction meet.

The predetermined number of X-passes may be three.

The predetermined number of Y-passes may be five.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional diagram of an implementation of a silicon carbide substrate during irradiation with a laser beam in a die street;

FIG. 2 is another cross sectional diagram of a silicon carbide substrate during pulsed laser irradiation in a die street during feeding of the silicon carbide substrate;

FIG. 3 is a cross sectional view of an implementation of a breaking system;

FIG. 4 are side and top views of a silicon carbide substrate prior to and during expansion using an expansion system;

FIG. 5 is a flow diagram with corresponding diagrams of a silicon carbide substrate during processing with an implementation of a lasering system, breaking system, and expansion system;

FIG. 6 is a cross sectional view of a silicon carbide substrate showing the location into the material of the silicon carbide substrate for laser irradiation in various X-direction passes (X-passes) and various Y-direction passes (Y-passes);

FIG. 7 is a flow chart of an implementation of a method of singulating silicon carbide;

FIG. 8 is a cross sectional photomicrograph of an X-axis sidewall of a silicon carbide die that is 100 microns thick following singulating;

FIG. 9 is a cross sectional photomicrograph of an Y-axis sidewall of a silicon carbide die that is 100 microns thick following singulating;

FIG. 10 is a cross sectional photomicrograph of an X-axis sidewall of a silicon carbide die that is 200 microns thick following singulating;

FIG. 11 is a cross sectional photomicrograph of an Y-axis sidewall of a silicon carbide die that is 200 microns thick following singulating;

FIG. 12 is a diagram of die samples used in three-point bending testing and an illustration of a three-points bending testing systems;

FIG. 13 is a cross sectional view of an implementation of a breaking system and a detail view of the tip of an implementation of an anvil during operation; and

FIG. 14 illustrates a sequence of processing steps for a silicon carbide substrate during an expansion process.

### DESCRIPTION

This disclosure, its aspects and implementations, are not limited to the specific components, assembly procedures or method elements disclosed herein. Many additional components, assembly procedures and/or method elements known in the art consistent with the intended methods of singulating semiconductor substrates will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such method of singulating semiconductor substrates, and implementing components and methods, consistent with the intended operation and methods.

The various methods of singulating semiconductor substrates disclosed herein utilize focused laser irradiation to form a damaged/modified region in the interior of the semiconductor substrate followed by breaking of the semiconductor substrate along the modified region and separation of a plurality of die from the semiconductor substrate using a tape expansion process. This overall process is referred to as “stealth dicing.” The stealth dicing process utilizes a lasering system, a breaking system, and an expansion system in combination with a substrate mounting system. While stealth dicing works in theory, the ability to use the process to accurately and repeatably singulate die from semiconductor substrates that can be included in semiconductor packages that can pass reliability testing involves significant experimentation that is semiconductor substrate material dependent. The semiconductor substrate material dependence is also a function of the specifications of the particular semiconductor substrate material which may include, by non-limiting example, semiconductor material type, crystallographic orientation, crystal plane alignment to surface, dopant concentration, dopant type, number of crystal imperfections/defects, type of crystal imperfections/defects, orientation of crystal imperfections/defects, semiconductor substrate thickness, semiconductor substrate size, die street orientation (X or Y), and many other attributes/parameters of a semiconductor substrate material.

Because of this, attempting to use stealth dicing parameters used for one semiconductor substrate type for a process of stealth dicing another semiconductor substrate type, or even for a different thickness of the same semiconductor substrate type, does not yield predictable results. Because of this, the significant experimentation detailed in this document was involved in developing a stealth dicing process specific to a particular semiconductor substrate material—in this case, silicon carbide. The results in this document obtained through experimentation were unpredictable and unexpected. Because of the extreme hardness of silicon carbide, dicing of the semiconductor substrate is slow and difficult using sawing with diamond coated/impregnated saw blade technology. The ability to utilize stealth dicing to produce die from a silicon carbide substrate that are capable of being included in packages that pass reliability tests may be very valuable. Such a process may increase the wafer per hour and units per hour that can be processed in a packaging/assembly process. Such a process may also allow for a shrinking of the die as the width of the die streets can be reduced because the die street width no longer needs to accommodate the kerf width of a given saw blade.

The silicon carbide substrates disclosed in the examples herein are N-type, 4H polytype, with a crystal orientation of 4 degrees off axis. The dislocation density of the silicon carbide substrates is about 5×10³ cm² with a micropipe density of less than 0.1 cm². The principles disclosed herein could also be applied to silicon carbide substrates with different dislocation densities and micropipe densities as well.

Referring to FIG. 1, a cross sectional diagram of an implementation of a silicon carbide substrate 2 during irradiation with a laser beam 4 in a die street using a lasering system. As illustrated, a lens 6 (or group of lenses) is used to focus the laser irradiation 4 onto/into the material of the silicon carbide substrate 2. As illustrated, as the focused laser beam 4 enters the material of the silicon carbide substrate 4, it is refracted at an angle 8 determined by the material and the particular wavelength/energy of the irradiation of the laser beam 4. The combination of the focus applied by the lens 6 and the refraction angle 8 determines the depth/location into the material of the silicon carbide substrate 2 at which the focal point 10 of maximum energy of the laser beam 4 is located. In FIG. 1, the laser beam 4 is traveling in a direction perpendicular with the paper (into and out of the paper). At the focal point 10, the energy of the focused irradiation of the laser beam 4 modifies the material of the silicon carbide substrate at the focal point to create a modified region.

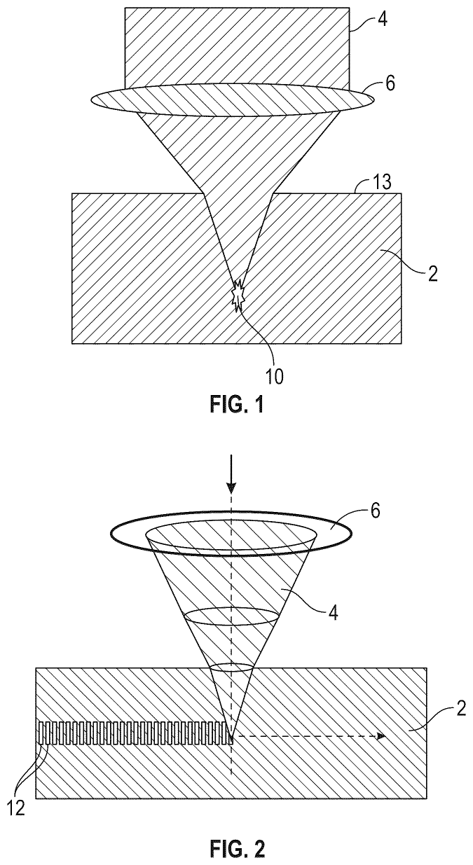

While in FIG. 1 the focal point 10 is represented as a point, in actual fact, the absorption of the energy of the irradiation from the laser beam 4 occurs in a more linear direction (in the form of a column/cylinder) in the direction of the laser beam into the material. Since the laser beam is operated in a pulsed mode rather than in a continuous wave mode, when the silicon carbide substrate 2 is fed/scanned at a fixed rate under the laser beam 4, a pattern of modified regions 12 corresponding with each focused pulse of the irradiation of the laser beam 4 can be observed in cross section, as illustrated in diagram of FIG. 2. Depending upon the overlap of each pulse with each other pulse set by the pulse repetition rate and/or feed speed of the silicon carbide substrate 2, the modified regions 12 may be present in the material of the silicon carbide substrate 2 as separated by unmodified material (as illustrated in FIG. 2) or may blend into one another to form a continuous/substantially continuous modified region. In this document, the terms “modified region” and “modified layer” are used synonymously for this reason.

The depth into the material of the silicon carbide substrate 2 of the focal point 10 can be adjusted using the lens 6 and/or altering the physical distance between the lens 6 and the top surface 13 of the silicon carbide substrate 2. Where multiple passes of the laser beam across the silicon carbide substrate 2 are used, the depth of each pass can be independently set to be the same, deeper into, or closer to the top surface 13 of the silicon carbide substrate 2 as the previous pass. Here the term “top surface” 13 refers to the surface of the silicon carbide substrate that faces the laser beam 4. The top surface could be either the side of the silicon carbide substrate that contains electrically active devices (active side) of the silicon carbide substrate, or the opposing surface of the silicon carbide substrate (backside) in various method implementations.

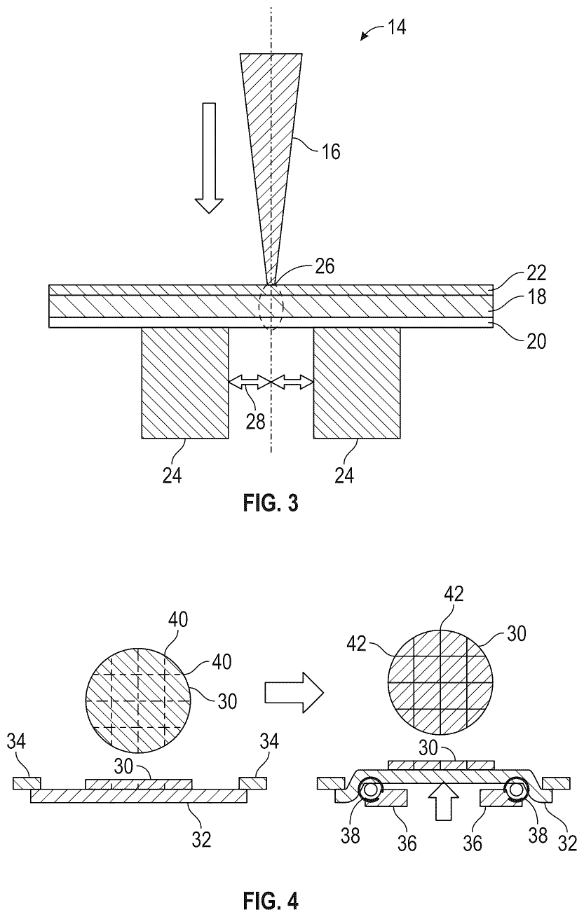

The various method implementations disclosed herein also employ two other major processes to achieve separation of the various die from the silicon carbide substrates, breaking, and expansion. Referring to FIG. 3, an implementation of a breaking system 14 is illustrated. Here the breaking system 14 includes a chopper 16 that is illustrated above substrate 18 upon which cover tape 20 and mounting tape 22 have been coupled on either side. Here the chopper 16 is positioned equidistant between portions of anvil 24 spaced apart by anvil distance 28 on each side to create a bending moment in the substrate 18 when the chopper is pressed down against the mounting tape 22. Determining the distance the chopper 16 should travel down against the mounting tape 22 during operation to produce a clean and repeatable breaking of the silicon carbide substrate at the modified region(s)/layer(s) in the die street is the result of several calibrations and calculations that involve the thickness of the cover tape 20, the thickness of the mounting tape 22, and the thickness of the silicon carbide substrate 18.

In a particular method implementation, a calibration of a chopper absolute height is performed by placing just cover tape over the anvil and lowering the chopper until the cover tape just reaches a point where it cannot be pulled out from underneath the chopper. In a particular implementation where the chopper is 91.34 mm long/high the chopper absolute height becomes 91.378 mm where the thickness of the cover tape is 0.038 mm. In various method implementations, a chopper over travel height is used to describe a distance that the chopper travels from a zero point of the drive motor to the surface of the silicon carbide substrate (which would be through the thickness of the mounting tape if present). To help take into account the thickness of the mount tape, cover tape, and substrate thickness for a given absolute chopper over travel height, a parameter called relative height by wafer is calculated and was varied in the experiments disclosed in this document.

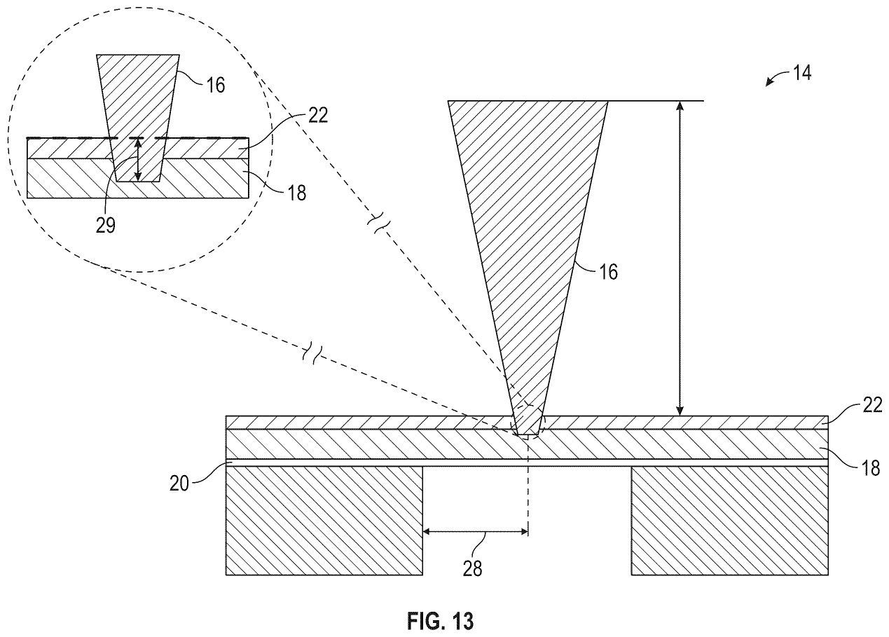

In a particular implementation with the previous specified chopper height, cover tape thickness, and for a 200 micron thick silicon carbide substrate the calculation for relative height by wafer is done by adding the silicon carbide substrate thickness, chopper over travel height, mounting tape thickness, cover tape thickness together and then subtracting 1378 microns. The result for a mounting tape thickness of 90 microns, cover tape thickness of 50 microns, chopper absolute over travel height is 1.14 mm, chopper absolute height of 91.14 mm is a chopper relative height by wafer of 102 microns. Referring to the larger view of the breaking system of FIG. 3 illustrated in the cross sectional view of FIG. 13, this chopper relative height by wafer 29 reflects the distance that the chopper pushes below the original level of the silicon carbide substrate 18 beneath the mounting tape 22 during downward deflection above the anvil 24 at the contact location 26. In other words, the chopper relative height by wafer 29 is a reflection of the amount of force that needs to be applied to the mounting tape/silicon carbide substrate/cover tape stack to achieve breaking of the silicon carbide substrate at a given anvil distance. In the studies in this document, the relative height by wafer 29 and actual anvil distance 28 demonstrated statistical significance when the occurrence of undivided die and presence of lateral cracks was assessed. In the study, a process window of relative height by wafer of between about 134 microns to about 144 microns and an X axis anvil distance between the chopper and the side of the anvil of about 3108 microns to about 3260 microns was identified as producing acceptable results with respect to both undivided die and presence of lateral cracks. In the Y axis direction, a relative height by wafer of between about 102 microns to about 120 microns at a Y axis anvil distance of about 2628 microns was identified as producing optimal results for undivided die (no effect on lateral cracking in the Y axis was identified in the study.

Following breaking of the die, since the die in a stealth dicing process are only separated by the actual width of the actual crack between the die, the ability to pick the die from the mounting tape without causing die chipping is low. To increase the ability for die picking to occur successfully post-breaking, the mounting tape is stretched/expanded using an expansion system. Referring to FIG. 4, a mounted silicon carbide substrate 30 is illustrated coupled to mounting tape 32 and frame 34 in a top down and in a side cross sectional view on the left. Here the broken lines 40 in the silicon carbide substrate 30 are represented as dotted lines because they are difficult to see visually because the very small width of the breaks. On the right, FIG. 4 illustrates the silicon carbide substrate 30 following an expansion process using a chuck that rises up a predetermined height/distance underneath the mounting tape 32 and contains rollers 38 that assist the tape with stretching uniformly across the width of the silicon carbide substrate 30. The goal of the tape expansion process is to produce sufficiently wide spaces 42 between the die to allow a die picking process to remove the singulated die from the tape without die chipping where the tape is not stretched too much to cause the die to sag during picking, thus hindering picking accuracy. The process variables that help assist with the expansion process include the height the chuck rises (expansion height), the temperature the expansion is carried out at, the time the tape is held by the chuck in the expansion position (hold time), and the speed the chuck rises (expansion speed). Following the expansion process, the mounted silicon carbide substrate is then moved to a die picking operation where the singulated die can then be picked and placed either directly onto a package substrate or in a picking tape that for subsequent use in a package assembly process.

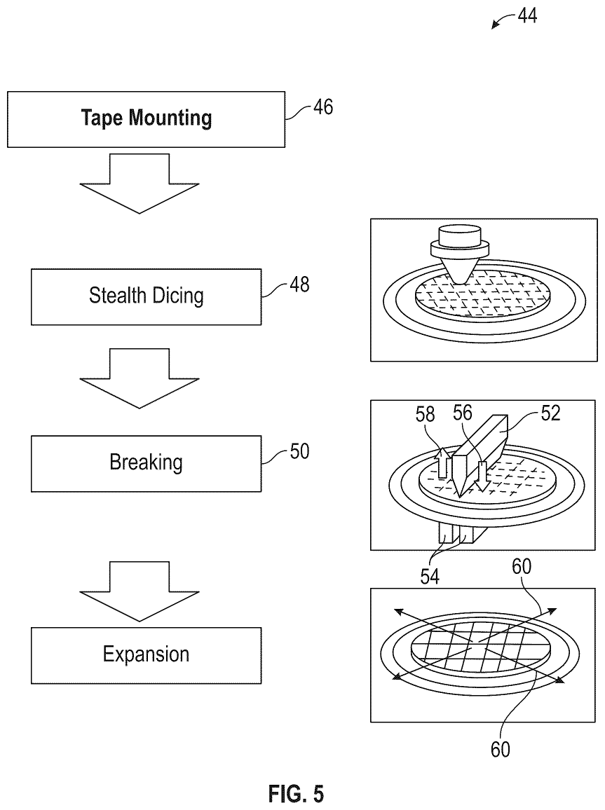

Referring to FIG. 5, a flow diagram of an implementation of a method of stealth dicing a silicon carbide substrate 44 is illustrated. As illustrated in FIG. 5, a tape mounting process (step 46) is used to apply a mounting tape and/or a cover tape prior to stealth dicing. In some method implementations, no tape may be present on the top surface of the silicon carbide substrate; in others, a tape (cover or mounting) may be applied to the top surface. Following the tape mounting process, the stealth dicing process (step 48) is carried out. As disclosed later this document, the stealth dicing process may involve multiple passes in the X-axis scribe lines/die streets (X-passes) and multiple passes in the Y-axis scribe lines/die streets (Y-passes) using a laser and lens. The laser and lens operate at a given wavelength and laser power. While the term “laser power” is used in this document, since the laser may be operated in pulsed mode, the “laser power” is a time averaged calculation of the average power of the set of pulses being produced by the laser in contrast with a constant output power from a laser operating in continuous wave mode.

Following the stealth dicing process, the silicon carbide substrate is then processed using the breaking system (step 50) which includes chopper 52 and anvil 54 which may be any disclosed in this document. As illustrated in FIG. 5, the breaking process employs the downward force 56 applied by the chopper 52 in combination with the corresponding moment 58 supplied by the two portions of the anvil spaced apart by the anvil distance which work to cause the substrate to break along the entire line of the chopper in the die street area of the silicon carbide substrate.

Following the breaking process, the mounted silicon carbide substrate is then processed by an expansion system which works to expand the substrate from the center point outward indicated by the four arrows 60 in FIG. 5. The result of the expansion system is to create sufficient spaces between the die to allow a die picking apparatus to allow a die picking apparatus to remove the various die without die chipping or issues caused by the sagging of overly stretched tape. The ability to do the expansion at a higher temperature than the picking process may allow the tape to deform plastically during the stretching process but then regain tensile strength for the picking process when it cools.

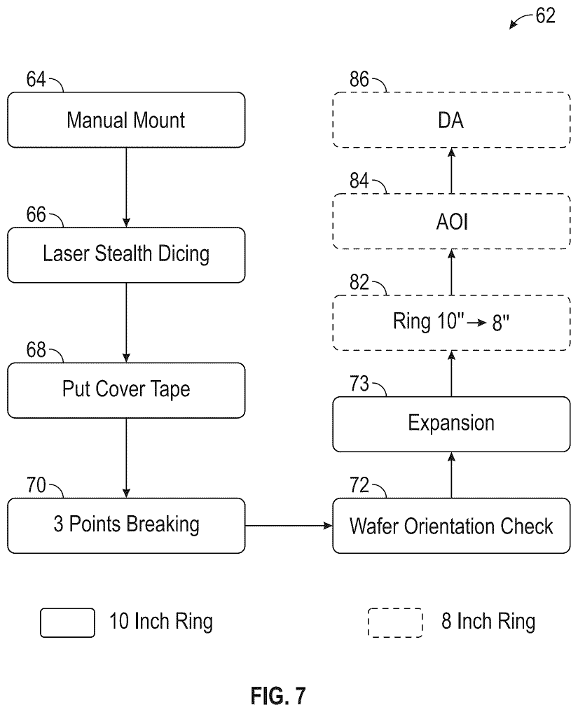

Referring to FIG. 7, a flow chart of another implementation of a method of singulating a silicon carbide substrate 62 is illustrated. In this implementation, a manual tape mounting process is employed (step 64) though in other implementations an automatic tape mounter may be used. Any laser stealth dicing process disclosed herein is them employed (step 66), followed by application of a cover tape to the back side of the silicon carbide substrate (the side that did not face the laser during lasering (step 68). The application of the cover tape may be done either manually or automatically using an automatic tape mounter in various method implementations. The silicon carbide substrate is then ready for processing using a breaking system like any disclosed herein (three points breaking process, step 70).

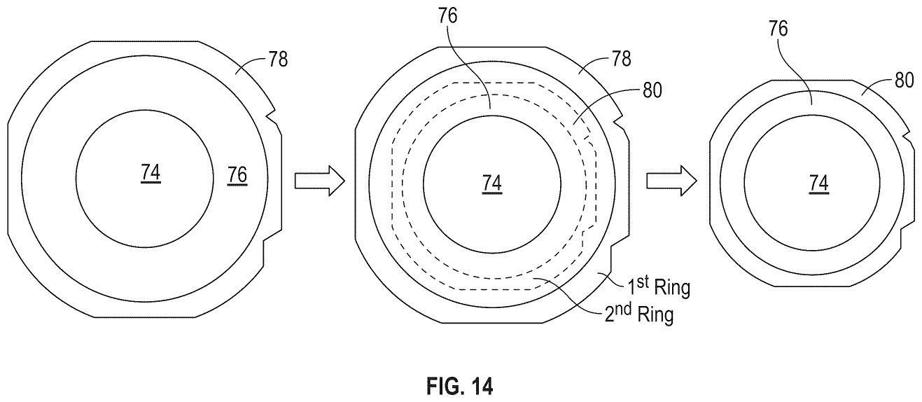

As illustrated in FIG. 7, the method includes a check of the orientation of the silicon carbide substrate (wafer orientation check, step 72) to ensure the wafer flat(s) (or other orientation structures) is in the proper orientation as the silicon carbide substrate is loaded onto the expansion system. This process ensures that the die streets are properly oriented relative to the expansion forces that will be applied as the chuck is raised underneath the during the expansion forces. This helps ensure uniform/desired spacing in between the die following the expansion process. The silicon carbide substrate then undergoes the expansion process which may any disclosed in this document (step 73). In a particular method implementation, with reference to FIG. 14, a remounting process (step 82) may be utilized. In various implementations, by non-limiting example, the original size of the silicon carbide substrate 74 is a six inch diameter mounted using mounting tape 76 to a ten inch diameter frame/ring 78. In this implementation, following the expansion process, a second eight inch ring 80 is applied to the mounting tape 76 while the silicon carbide substrate 74 is still mounted and the first ring 78 is then removed in a second mounting process. During this process, the now stretched mounting tape is tightened as it is applied to the second ring 80, which can further prevent drooping/sagging during subsequent die picking processing. The silicon carbide substrate 74 is then processed during subsequent steps while attached to the second ring 80. As indicated in FIG. 7, those process steps with solid line outlines are those done with the first ring and those in dotted lines are those performed with the second ring in place.

These additional process operations may include, as illustrated in FIG. 7, an automated optical inspection (AOI, step 84) followed by a die picking operation that occurs either simultaneously with or prior to a die attach process where each die is attached to a substrate during a die packaging operation (DA, step 86).

Various process parameters for the various stealth dicing method implementations are disclosed in this document. These are exemplary and reflect the results of sets of a comprehensive statistically designed experiments following by reliability testing of assembled die to validate that the singulation processes provide long-term stability for a desired design lifetime.

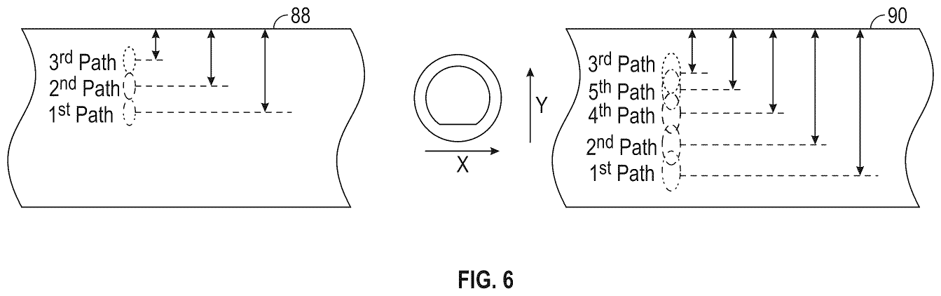

Referring to FIG. 6, a diagram of the laser passes in an implementation of a lasering process with multiple passes the X direction 88 and in the Y direction 90 is illustrated. Here, three passes in each X die street are conducted and five passes in each Y die street are carried out. FIG. 6 indicates that in this particular method implementation, the three passes in the X die streets are carried out where the first path is at a first deepest distance into the material of the silicon carbide substrate, the second path is at a second distance into the material of the silicon carbide substrate that is not as deep as the first, and the third path is at a third distance into the material of the silicon carbide substrate that is the least deep as the second. Put differently, the first path in the X direction is further into the thickness of the silicon carbide substrate than the second path, and the second path is further into the thickness than the third path.

In the Y direction, as illustrated, the five paths are carried out where the first path is at a first deepest distance into the silicon carbide substrate and the second path is a second less deep distance into the silicon carbide substrate. The third path is at third, least deep distance into the silicon carbide substrate. The fourth path is at a fourth distance less deep than the second path, and the fifth path is at a fifth distance less deep than the fourth path but deeper than the third distance of the third path. Put differently, the first distance of the first Y-pass is further into the thickness of the silicon carbide substrate than the second distance of the second Y-pass, the second distance is further into the thickness than the third distance of the third Y-pass, the fourth distance of the fourth Y-pass is further into the thickness than the third distance, and the fourth distance in further into the thickness than the fifth distance of the fifth Y-pass. These same paths in these relative distances and orders can be employed for both 100 micron thick silicon carbide substrates and 200 micron thick silicon carbide substrates.

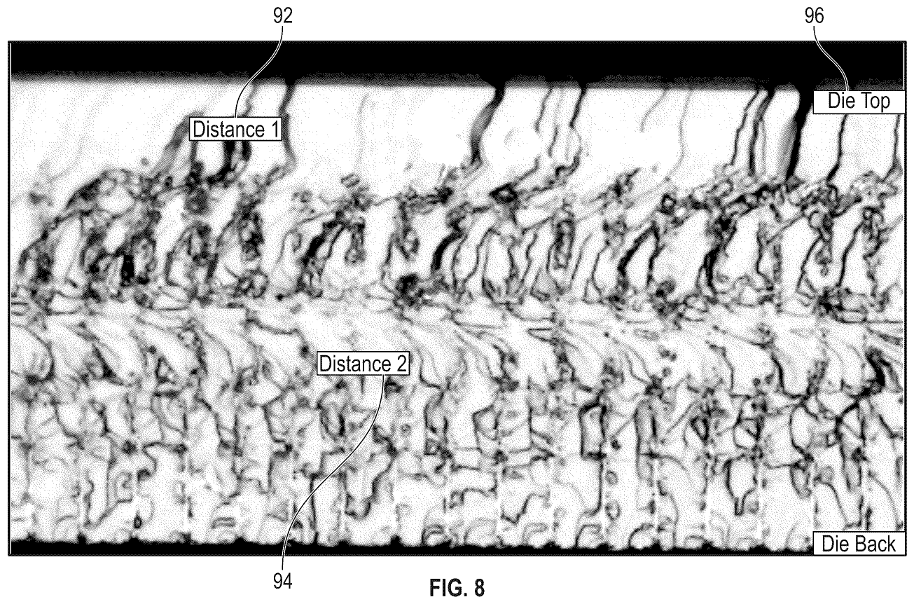

The effect of the multiple passes is to create modified regions/layers within the thickness of the silicon carbide substrate. Referring to FIG. 8, a photomicrograph of the as-singulated sidewall in an X-direction of a silicon carbide substrate with a thickness of 100 microns following stealth dicing and breaking is illustrated. As illustrated, a first modified region is located at a first distance 92 (Distance 1) and a second modified region is located at a second distance 94 (Distance 2) into the thickness of the silicon carbide substrate. It has been noted that consistent breaking performance is achieved when the first modified region and the second modified region meet. It has been noted that, in the X-direction die streets, the meeting of the first and second modified regions occurs within a range of first distances and second distances. In a particular method implementation, the range of first distances is about 20 microns from the top surface 96 to about 32 microns from the top surface 96 and the range of second distances is between about 39 microns to about 56 microns from the top surface 96.

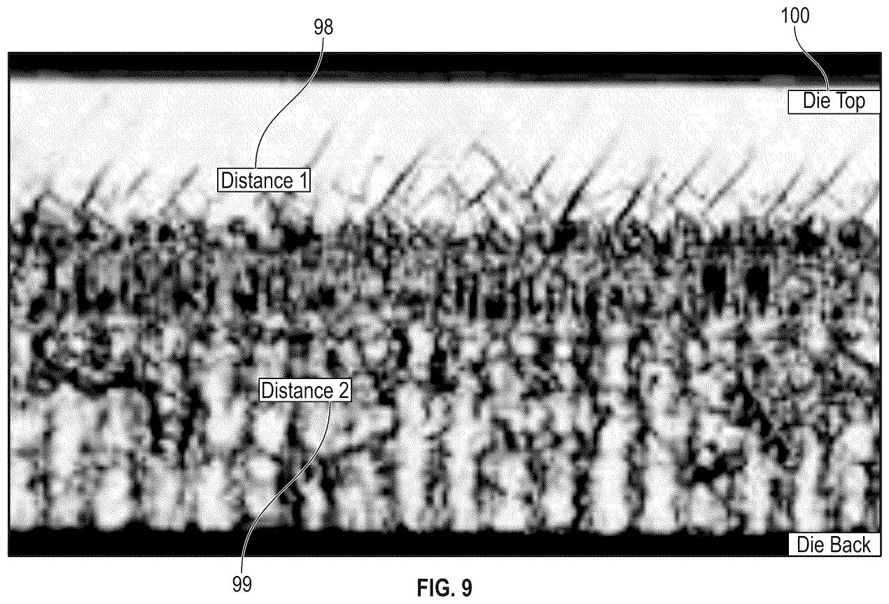

Referring to FIG. 9, a photomicrograph of an as-singulated sidewall of a silicon carbide substrate in a Y-direction with a thickness of 100 microns following stealth dicing and breaking is illustrated. Similar to the photomicrograph of FIG. 8, a first modified region is located at first distance 98 (Distance 1) and a second modified region is located at a second distance 99 (Distance 2) from the top surface 100 of the silicon carbide substrate. In the Y-direction, consistent breaking performance has also been noted to occur where the meeting of the first and second modified regions is within a range of first distances and second distances. In a particular method implementation, the range of first distances is between about 21 microns to about 33 microns from the top surface 100 and the range of second distances is between about 38 microns to about 58 microns from the top surface 100.

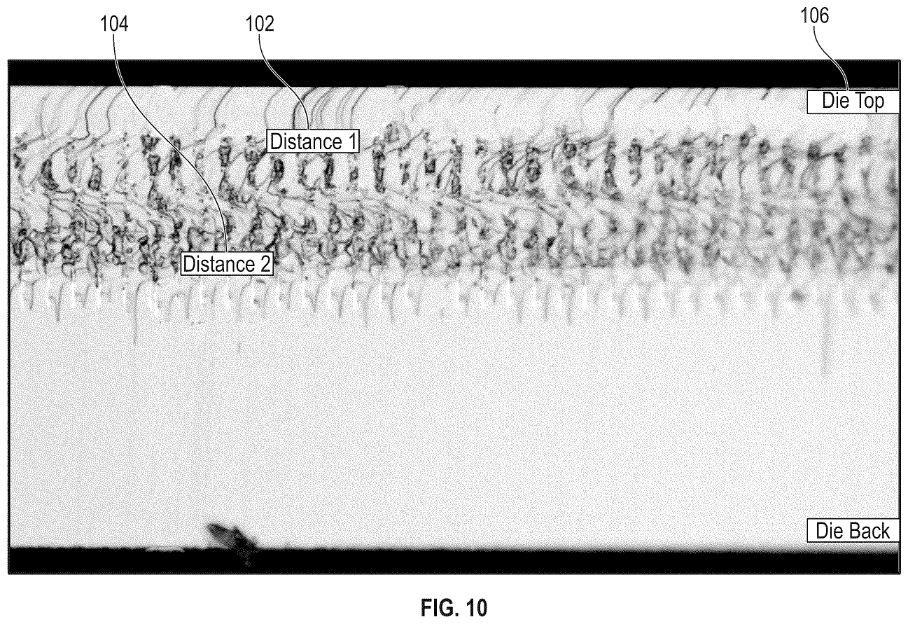

For silicon carbide substrates with a thickness of 200 microns, a similar phenomenon of consistent breaking performance has been noted where a first modified layer and second modified layer meet. Referring to FIG. 10, a photomicrograph of an as-singulated sidewall of a silicon carbide substrate in an X-direction with a thickness of 200 microns following stealth dicing and breaking is illustrated. Here a first modified region is located at first distance 102 (Distance 1) and the second modified region is located at second distance 104 (Distance 2) from the top surface 106 of the silicon carbide substrate. Note in this implementation that substantially the entirety of the first and second modified regions is located in the upper 50%/half of the thickness of the silicon carbide substrate. This differs from the positioning of the first and second modified regions of the 100 micron thick silicon carbide substrate of FIGS. 8 and 9 which are located approximately on each side of the centerline of the thickness of the substrate (substantially centered on the centerline). This ability to achieve consistent breaking performance for a substrate twice as thick with placement of the modified layers in the upper half of the silicon carbide substrate thickness is a surprising and unexpected result when compared with the results achieved with the 100 micron thick silicon carbide substrate. In the X-direction for 200 micron thick silicon carbide substrates, consistent breaking performance has been observed to occur where the range of first distances is between about 22 microns to about 35 microns and where the range of second distance is between about 43 microns to about 62 microns from the top surface 106.

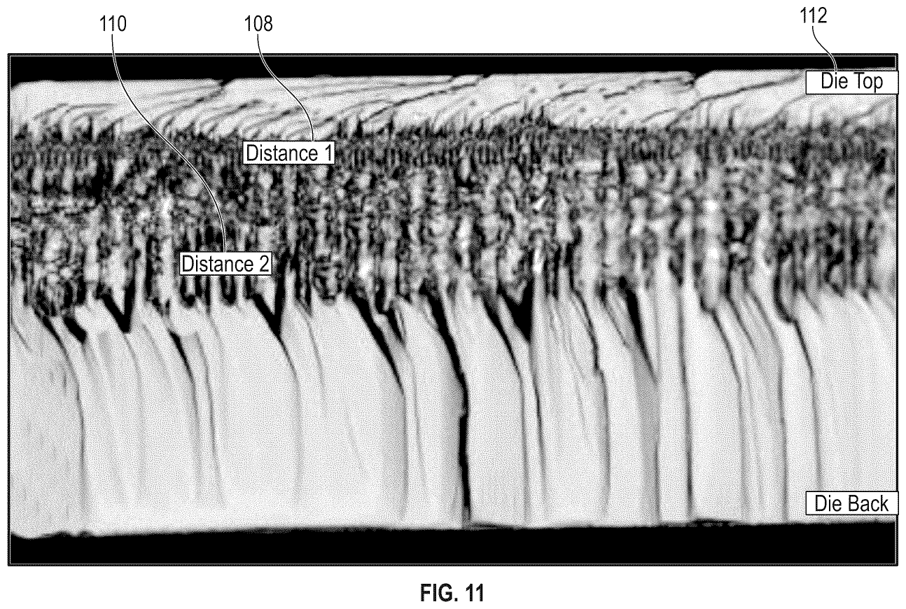

Referring to FIG. 11, a photomicrograph of an as-singulated sidewall of a silicon carbide substrate following stealth dicing and breaking is illustrated in a Y-direction. Here a first modified region is located at first distance 108 (Distance 1) and second modified region is located at second distance 110 (Distance 2) from the top surface 112 of the silicon carbide substrate. Again, as in the X-direction, the first and second modified regions are located substantially in the upper 50%/half of the thickness of the 200 micron thick silicon carbide substrate in contrast with the photomicrographs of FIGS. 8 and 9 which in the Y-direction are also located approximately on each side of the centerline of the thickness of the substrate (substantially centered on the centerline). Again, as in the X-direction, the ability to achieve consistent breaking performance where the first and second modified regions are located in the upper half of the thickness of the silicon carbide substrate is an unexpected and surprising result given the results for a 100 micron thick silicon carbide substrate. In the Y-direction, for 200 micron thick silicon carbide substrates, consistent breaking performance has been observed where the range of first distances is between about 21 microns to about 36 microns and the range of second distances is between about 44 microns to about 63 microns from the top surface 112 of the silicon carbide substrate.

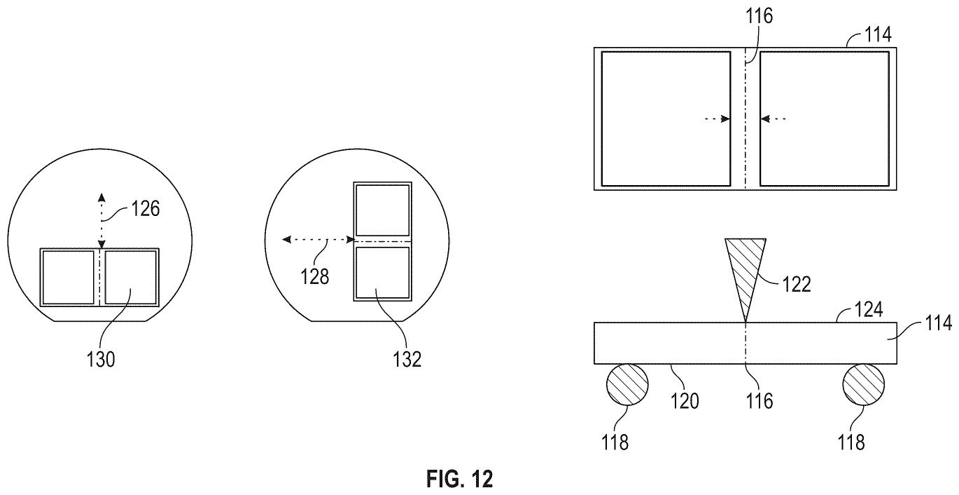

The breaking strength of the die at the die streets following stealth dicing was also measured using a three-point bending testing technique. This three-point bending technique was used to collect data that is different from ordinary die strength data collected using three-point bending. In ordinary die strength data collection, a single die is subjected to the three-point bending to assess the die's strength following thinning and/or singulation. In the testing done here, referring to FIG. 12, two die 114 were singulated from a silicon carbide substrate following stealth dicing between the two die 114 but without breaking being carried out in the die street 116 between the two die. The two die were then placed onto two supports 118 spaced on each side of the die street with the front (active) side 120 of the two die 114 in contact with the two supports 118. A chopper 122 is then placed against the back side (124) of the two die 114 at the die street 116 and then pressed against the back side 124 until the two die break at the die street 116. As illustrated in FIG. 12, the breaking strength of the die streets 126 in the Y direction was tested using two die 130 and the breaking strength of the die streets in 128 in the X direction was tested using two die 132. In a particular implementation, the breaking strength for 100 micron thick silicon carbide die was observed to be on the average higher in the Y direction die streets than in the X direction die streets by about 1 Newton.

Various statistically designed experiments were conducted with 100 micron thick and 200 micron thick silicon carbide substrates like those disclosed herein to determine those factors that affected stealth dicing and breaking quality/capability. The results of various of these experiments are reported in summary form in this document for the purposes of disclosing the ranges of operating parameters where maximum desirability was achieved and where Monte Carlo simulations indicated that defect rates would be 0%.

In the experiments, initially a full factorial design analyzing laser parameters with three factors at two levels with two center points was run with the laser scan speed, the laser power, and laser focus height as the factors with ¼ of a wafer used as the sample size for each leg. The cutting direction in the X direction was from left to right and the cutting direction in the Y direction was from the wafer flat to the opposite side of the wafer. An analysis of the results indicated that none of the three factors was statistically significant when evaluated against the various key parameters but one of the legs had the lowest defect quantity and lowest failure rate relative to the key parameters analyzed and was thus selected as a starting point for further experimentation.

A second designed experiment analyzing the relevant breaking parameters of the breaking system was then carried out to characterize the core process variables and settings and assess their effects. Data from the X direction and the Y direction were analyzed separately to evaluate statistical significance of the various parameters identified. In the X-direction, the over travel height and anvil distance were identified as having a statistically significant effect and were selected for subsequent experimental analysis in combination with the laser parameters. In this experiment, a range of relative height was identified as being between about 134 microns to about 144 microns and a range of anvil distance was identified as being between 3108 microns to about 3260 microns. In the Y-direction, none of the parameters tested proved to be statistically significant in this experiment and so a range of relative height values between about 102 microns to about 120 microns with an anvil distance of about 2628 microns was selected for subsequent experimental analysis.

A third designed experiment was then carried out that combined parameters from the laser experiments and the breaking system experiments. Due to the larger number of parameters/factors involved in the combined experiment, a fractional factorial design was employed using 5 factors with two levels with three center points. In this experiment, the laser factors included focus height, laser power in Watts, and scan speed in mm/second and the breaking system factors included overtravel height and anvil distance. A sample size of one wafer was employed in each leg of the experiment. The data was analyzed versus various key parameters in the X direction where the statistically significant factors identified were over travel height, laser power, focus height and over travel height interaction, over travel height and anvil distance interaction, and focus height and scan speed interaction. The experiment also identified a range of values for the various parameters in the X direction: focus height between about −1 um to about 1 um, laser power between about 0.17 W to about 0.19 W, scan speed between about 500 mm/sec to about 550 mm/sec, over travel height between about 1.14 mm to about 1.15 mm, and an anvil distance between about 0.3 to about 0.34 mm.

The analysis of the data in the Y direction indicated that the statistically significant factors and interactions were over travel height, focus height and over travel height interaction, scan speed, anvil distance, focus height and speed interaction, and the scan speed and over travel height interaction. The experiment also identified a range of values for the various parameters in the Y direction: focus height between about −1 um to about 1 um, laser power between about 0.21 W to about 0.25 W, scan speed between about 500 mm/sec to about 550 mm/sec, over travel height between about 1.14 mm to about 1.155 mm, and an anvil distance between about 0.38 mm to about 0.40 mm. By inspection, several of the ranges and values of the parameters in the Y direction differ from those identified in the X direction.

A final laser parameter and breaking system experiment was run to evaluate improved parameter ranges for focus height, laser power, scan speed, over travel height, and anvil distance with lower and upper cliff values and low, mid, and, high values for each of the parameters. The resulting set of parameters that resulted in the highest yield was then selected to generate a set of die for use in development of parameters for the expansion system was used. With the lasering system, breaking system, and expansion system improved parameters determined, further evaluations of backside and sidewall chipping, die breaking strength (using the apparatus disclosed herein), and finally reliability testing was carried out. The reliability testing used included temperature cycle (−5 C to 150 C), power cycle, and Highly Accelerated Stress Testing (HAST) at 130 C, 85% humidity, and 520 V (for these particular silicon carbide power devices). The results of the reliability testing indicated that die singulated using the determined lasering system, breaking system, and expansion system parameters meet the success criteria and the parameters were now ready for use in a production process of stealth dicing of silicon carbide substrates.

Table 1 includes the set of determined lasering parameters used for both 100 micron thick and 200 micron thick silicon carbide substrates that resulted from the foregoing experimentation:

TABLE 1

| | | | Focus | Scan | | | Laser | Focus | Scan |
|---|---|---|---|---|---|---|---|---|---|
| | | | Height | Speed | | | Power | Height | speed |
| Path | Wavelength | Power (W) | (um) | (mm/s) | Path | Wavelength | (W) | (um) | (mm/s) |
| X0 | 1064 nm | 0.18 | −26 | 525 | Y0 | 1064 nm | 0.23 | −26 | 510 |
| X1 | 1064 nm | 0.18 | −19 | 525 | Y1 | 1064 nm | 0.23 | −21 | 510 |
| X2 | 1064 nm | 0.18 | −13 | 525 | Y2 | 1064 nm | 0.04 | −13 | 150 |
| | | | | | Y3 | 1064 nm | 0.23 | −17 | 510 |
| | | | | | Y4 | 1064 nm | 0.23 | −14 | 510 |

Table 2 includes the set of determined breaking parameters for use with the breaking system for about 100 micron thick silicon carbide substrates. The breaking sequence involves breaking the Y direction streets first followed by breaking the X direction streets second.

TABLE 2

| Direction | Over Travel Height | Anvil Distance | Chopper Drop |
|---|---|---|---|
| (see FIG. 6) | (mm) | (ratio multiplier) | Speed (mm/s) |
| X | 1.2 | 0.39 | 20 mm/s |
| Y | 1.2 | 0.39 | 20 mm/s |

Table 3 includes the set of determined breaking parameters for use with the breaking system for about 200 micron thick silicon carbide substrates. The breaking sequence involves breaking the Y direction streets first followed by breaking the X direction streets.

TABLE 3

| Direction | Over Travel Height | Anvil Distance | Chopper Drop |
|---|---|---|---|
| (see FIG. 6) | (mm) | (ratio multiplier) | Speed (mm/s) |
| X | 1.12 | 0.39 | 20 mm/s |
| Y | 1.12 | 0.39 | 20 mm/s |

Table 4 is the set of determined expansion parameters for use with the expansion system for both about 100 micron and about 200 micron thick silicon carbide substrates.

TABLE 4

| Expansion Height | Temperature | Hold Time | Expansion Speed |
|---|---|---|---|
| 8 mm | 60 C. | 30 seconds | 10 mm/ss |

The ability to singulate silicon carbide substrates using stealth dicing may lead to additional advantages through the elimination of processing steps used in sawing. For example, the elimination of high pressure water jets and pressurized air on the top surface of the wafer during singulation can lead to no observable solderable top metal peeling defects being observed post-stealth dicing. The elimination of chipping from a saw blade may allow for shrinking of the die streets and corresponding wafer density increase. Other process improvements may be observed as the substrates per hour or wafers per hour that can be processed using stealth dicing may be 11.3 wafers per hour in contrast with other processes like dual saw blade cutting (2.4 wafers per hour), Sakasa-blade cutting (9 wafers per hour), or laser full cutting (8 wafers per hour). Since the stealth dicing process does not involve use of water, surfactant chemical, or any blade consumables, a significant reduction of cost of ownership compared to a dual sawing process could also be achieved.

In places where the description above refers to particular implementations of method of singulating semiconductor substrates and implementing components, sub-components, methods and sub-methods, it should be readily apparent that a number of modifications may be made without departing from the spirit thereof and that these implementations, implementing components, sub-components, methods and sub-methods may be applied to other methods of singulating semiconductor substrates.

What is claimed is:

1. A method of singulating silicon carbide comprising:
providing a silicon carbide substrate comprising a thickness; and
in a plurality of X-direction die streets:
irradiating the silicon carbide substrate in an X-direction with a laser beam focused at a first focal point a first distance into the thickness in a first X-pass;
irradiating the silicon carbide substrate in the X-direction with the laser beam focused at a second focal point a second distance into the thickness in a second X-pass;
irradiating the silicon carbide substrate in the X-direction with the laser beam focused at a third focal point a third distance into the thickness in a third X-pass; and
in a plurality of Y-direction die streets:
irradiating the silicon carbide substrate in a Y-direction with the laser beam focused a first focal point a first distance into the thickness in a first Y-pass;
irradiating the silicon carbide substrate in a Y-direction with the laser beam focused a second focal point a second distance into the thickness in a second Y-pass;
irradiating the silicon carbide substrate in a Y-direction with the laser beam focused a third focal point a third distance into the thickness in a third Y-pass;
irradiating the silicon carbide substrate in a Y-direction with the laser beam focused a fourth focal point a fourth distance into the thickness in a fourth Y-pass;
irradiating the silicon carbide substrate in a Y-direction with the laser beam focused a fifth focal point a fifth distance into the thickness in a fifth Y-pass; and
breaking the silicon carbide substrate in the X-direction and in the Y-direction along the plurality of X-direction die streets and the plurality of Y-direction die streets, respectively, using an anvil; and
expanding a tape coupled to the silicon carbide substrate to separate a plurality of die from the silicon carbide substrate.

2. The method of claim 1, wherein the first distance in the first X-pass is further into the thickness than the second distance in the second X-pass and the second distance in the second X-pass is further into the thickness than the third distance in the third X-pass.

3. The method of claim 1, wherein the first distance in the first X-pass is −26 microns, the second distance in the second X-pass is −19 microns, and the third distance in the third X-pass is −13 microns.

4. The method of claim 1, wherein:
the first distance in the first Y-pass is further into the thickness than the second distance in the second Y-pass;
the second distance in the second Y-pass is further into the thickness than the third distance in the third Y-pass;
the fourth distance in the fourth Y-pass is further into the thickness than the third distance in the third Y-pass; and
the fourth distance in the fourth-Y-pass is further into the thickness than the fifth distance in the fifth Y-pass.

5. The method of claim 1, wherein the first distance in the first Y-pass is −26 microns, the second distance in the second Y-pass is −21 microns, the third distance in the third Y-pass is −13 microns, the fourth distance in the fourth Y-pass is −17 microns, and the fifth distance in the fifth Y-pass is −14 microns.

6. The method of claim 1, wherein a scan speed used in the first Y-pass, the second Y-pass, the fourth Y-pass, and the fifth Y-pass is 510 mm/second and a scan speed used in the third Y-pass is 150 mm/second.

7. The method of claim 1, wherein a scan speed used in the first X-pass, the second X-pass, and the third X-pass is 525 mm/second.

8. The method of claim 1, wherein:
a laser power used in the first X-pass, the second X-pass, and the third X-pass is 0.18 W;
a laser power used in the first Y-pass, the second Y-pass, the fourth Y-pass, and the fifth Y-pass is 0.23 W; and
a laser power used in the third Y-pass is 0.04 W.

9. A method of singulating silicon carbide comprising:
providing a silicon carbide substrate comprising a thickness; and
in a plurality of X-direction die streets, irradiating the silicon carbide substrate in an X-direction with a laser beam focused at a focal point a distance into the thickness in a predetermined number of X-passes;
in a plurality of Y-direction die streets, irradiating the silicon carbide substrate in a Y-direction with the laser beam focused a focal point a distance into the thickness in a predetermined number of Y-passes;
breaking the silicon carbide substrate first in the Y-direction and then in the X-direction an along the plurality of X-direction die streets and the plurality of Y-direction die streets, respectively, using an anvil at a predetermined over travel height, an anvil distance of 0.39 mm, and a chopper drop speed of 20 mm/second; and
expanding a tape coupled to the silicon carbide substrate to separate a plurality of die from the silicon carbide substrate at a temperature of 60 C.

10. The method of claim 9, wherein when the thickness of the silicon carbide substrate is 100 microns, the predetermined over travel height is 1.2 mm.

11. The method of claim 9, wherein when the thickness of the silicon carbide substrate is 200 microns, the predetermined over travel height is 1.12 mm.

12. The method of claim 9, wherein expanding the tape further comprises expanding at an expansion height of 8 mm, an expansion speed of 10 mm/second, and a hold time of 30 seconds.

13. A method of singulating silicon carbide comprising:
providing a silicon carbide substrate comprising a thickness; and
in a plurality of X-direction die streets, irradiating the silicon carbide substrate in an X-direction with a laser beam focused at a focal point a first depth into the thickness in a predetermined number of X-passes to form a first modified region beginning a first distance into the thickness and a second modified region a second distance into the thickness;
in a plurality of Y-direction die streets, irradiating the silicon carbide substrate in a Y-direction with the laser beam focused a focal point a second depth into the thickness in a predetermined number of Y-passes to form a first modified region a first distance into the thickness and a second modified region a second distance into the thickness;
breaking the silicon carbide substrate first in the Y-direction and then in the X-direction along the plurality of X-direction die streets and the plurality of Y-direction die streets, respectively, using an anvil; and
expanding a tape coupled to the silicon carbide substrate to separate a plurality of die from the silicon carbide substrate.

14. The method of claim 13, wherein, in the X-direction, the first distance is between 20 microns to 32 microns and the second distance is between 39 microns and 56 microns when the thickness of the silicon carbide substrate is 100 microns.

15. The method of claim 13, wherein, in the Y-direction, the first distance is between 21 microns to 33 microns and the second distance is between 38 microns and 58 microns when the thickness of the silicon carbide substrate is 100 microns.

16. The method of claim 13, wherein, in the X-direction, the first distance is between 22 microns to 35 microns and the second distance is between 43 microns and 62 microns when the thickness of the silicon carbide substrate is 200 microns.

17. The method of claim 13, wherein, in the Y-direction, the first distance is between 43 microns to 62 microns and the second distance is between 44 microns and 63 microns when the thickness of the silicon carbide substrate is 200 microns.

18. The method of claim 13, wherein consistent breaking of the silicon carbide substrate occurs when the first modified region and the second modified region in the X-direction meet and when the first modified region and the second modified region in the Y-direction meet.

19. The method of claim 13, wherein the predetermined number of X-passes is three.

20. The method of claim 13, wherein the predetermined number of Y-passes is five.
